(19) United States
(12) Patent Application Publication
(10) Pub. No.: US 2025/0130253 A1
(43) Pub. Date: Apr. 24, 2025

(54) MANAGEMENT SYSTEM FOR PROBE CARDS

(71) Applicant: STAR TECHNOLOGIES, INC., HSINCHU CITY (TW)

(72) Inventors: CHOON LEONG LOU, HSINCHU CITY (TW); YU-MING CHIEN, ZHUBEI CITY (TW); HO-YEH CHEN, HSINCHU CITY (TW)

(21) Appl. No.: 18/395,072

(22) Filed: Dec. 22, 2023

(30) Foreign Application Priority Data
Oct. 23, 2023 (TW) 112140454

(51) Int. Cl. G01R 1/067; G01R 1/073; G01R 35/00

(52) U.S. Cl. CPC G01R 1/06705; G01R 1/07342; G01R 35/00

(57) ABSTRACT

The present disclosure provides a management system for probe cards. The management system includes: a storage device, an inspection device and a conveying device. The conveying device is configured to: receive a first conveying device control signal; and convey, according to the first conveying device control signal, a first probe card of the probe cards from a DUT tester device to the inspection device. The inspection device is configured to inspect whether a function of the first probe card is normal. The first probe card is stored in the storage device after the function of the first probe card is inspected as normal.

### CROSS REFERENCE TO RELATED APPLICATION

This application claims priority of Taiwan patent application No. 112140454 filed on Oct. 23, 2023, which is incorporated by reference in its entirety.

### TECHNICAL FIELD

The present disclosure relates to management systems for probe cards and, more particularly, to a probe card automatic management system having an inspection device and a conveying device.

### DISCUSSION OF THE BACKGROUND

According to prior art, semiconductor DUTs (devices under test) undergo electrical tests with probe cards and testers. Owing to the diversity of semiconductor DUT design, probe card design varies with semiconductor DUT design. The probe cards are usually customized products, because every required probe card varies from semiconductor DUT to semiconductor DUT. Therefore, related industries not only need to use numerous different probe cards but also require management systems to manage numerous probe cards. However, at present, related industries manage the probe cards mostly manually to the detriment of efficiency and precision.

Although various automatic warehousing solutions are available in different fields, existing automatic warehousing solutions cannot be integrated into and applied to the management of probe cards because of the characteristics of probe card management. Therefore, it is imperative to provide a fully automated probe card management system.

The above description of the prior art serves as an introduction to background technology but does not imply admitting that the described prior art discloses any subject matters of the disclosure or constitutes the prior art of the disclosure. Furthermore, the described prior art should not be deemed part of the disclosure.

### SUMMARY

It is an objective of the disclosure to provide a management system for probe cards to overcome the aforesaid drawback of the prior art, i.e., inefficient, imprecise probe card management.

An embodiment of the disclosure provides a management system for a plurality of probe cards, comprising a storage device, inspection device and conveying device. The conveying device receives a first conveying device control signal and conveys a first probe card of the probe cards from a DUT testing device to the inspection device according to the first conveying device control signal. The inspection device inspects whether a function of the first probe card is normal. The first probe card is stored in the storage device after the function of the first probe card is inspected as normal.

Therefore, the management system for the probe cards according to the disclosure is capable of performing probe card management efficiently and precisely, because the management system has a conveying device for automatically performing probe card movement between different devices according to a signal, and has automatic storage device and inspection device.

The technical features and advantages of the disclosure are described generally and extensively above to render the detailed description of the disclosure below comprehensible. Other technical features and advantages of the subject matters of the claims of the disclosure are described below. Persons skilled in the art understand that concepts and specific embodiments presented below can be easily used to amend or design any other structures or manufacturing processes and thereby achieve the same objective as the disclosure. Persons skilled in the art also understand that the aforesaid equivalent constructions cannot depart from the spirit and scope defined in the appended claims of the disclosure.

### BRIEF DESCRIPTION OF THE DRA WINGS

Persons skilled in the art can gain insight into the disclosure by referring to the embodiments, claims and drawings of the disclosure. In the drawings, like components are denoted by like reference numerals.

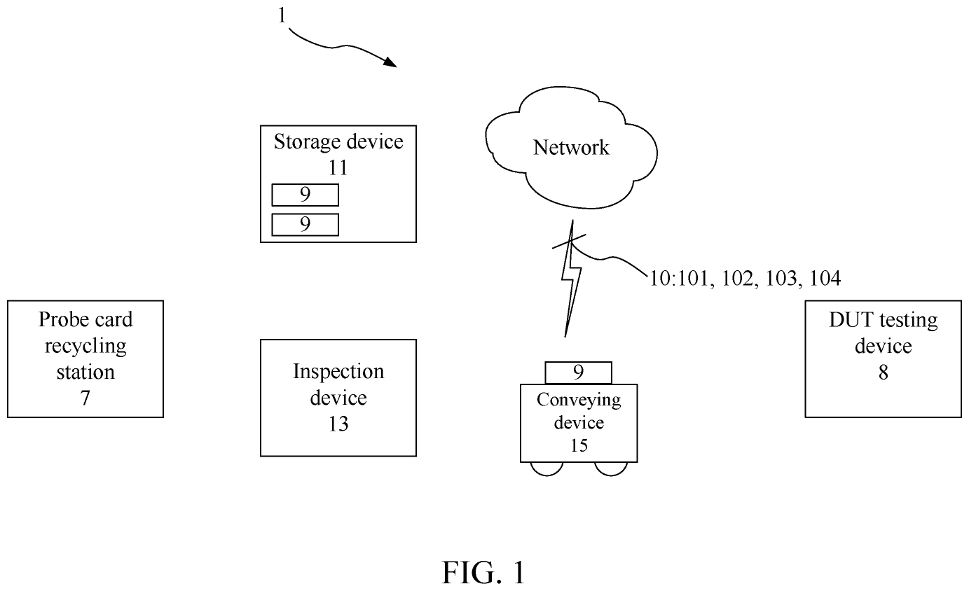

FIG. 1 is a schematic view of a management system for probe cards according to some embodiments of the disclosure.

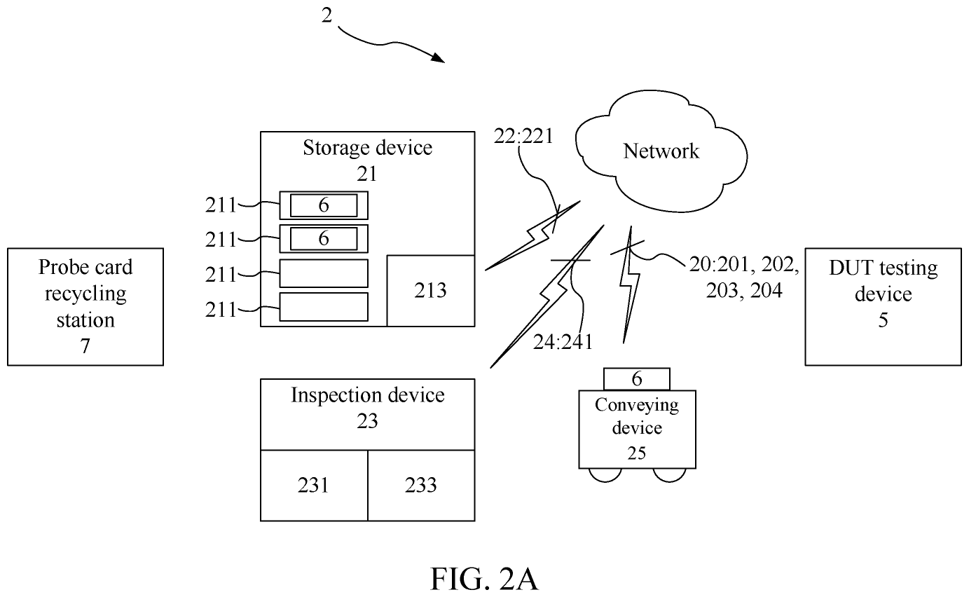

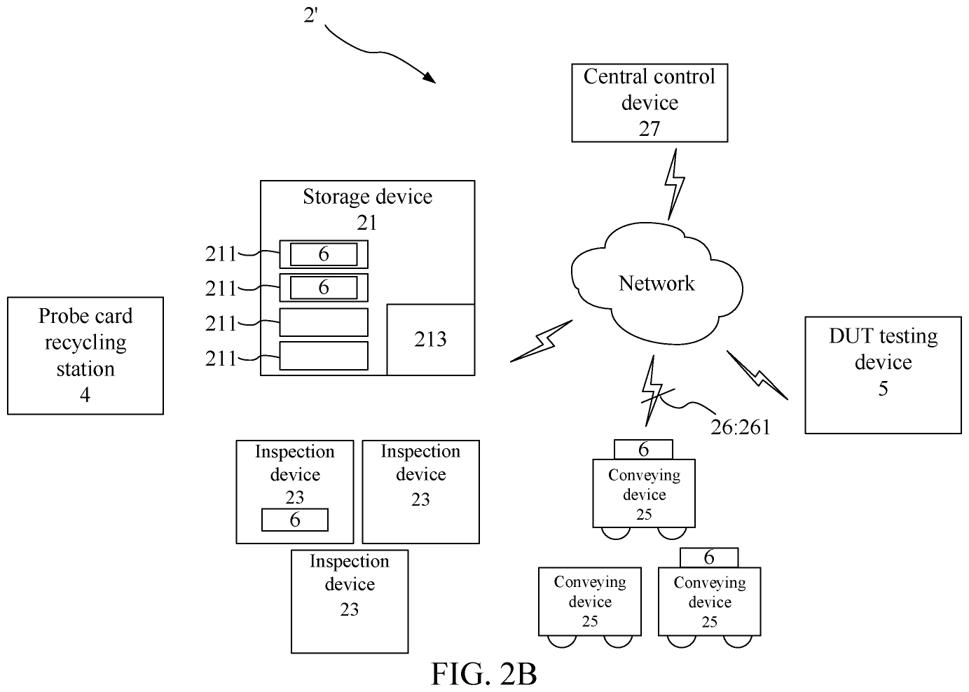

FIG. 2A is a schematic view of the management system for probe cards according to some embodiments of the disclosure.

FIG. 2B is a schematic view of the management system for probe cards according to some embodiments of the disclosure

### DETAILED DESCRIPTION

The description below is accompanied by and incorporated into some of the drawings to illustrate the embodiments of the disclosure. However, the disclosure is not limited to the embodiments. The embodiments described below may be appropriately integrated to attain any other embodiments.

The purpose of the expressions “an embodiment,” “embodiment,” “exemplary embodiment,” “other embodiments” and “another embodiment” used herein is to state that the embodiments of the disclosure can include specific features, structures or characteristics. However, not every embodiment must include the specific features, structures or characteristics. Furthermore, repeated use of the expression “in an embodiment” does not necessarily imply referring to the same embodiment, as the possibility of referring to the same embodiment should not be ruled out.

The description below goes into detail about steps and structures in order for the disclosure to be fully comprehensible. Obviously, the embodiments of the disclosure do not place any limitations on specific details well known among persons skilled in the art. In addition, well-known structures and steps are not reiterated herein such that no limitations are unnecessarily placed on the disclosure. Preferred embodiments of the disclosure are described in detail below. However, in addition to the detailed description, the disclosure can be extensively implemented in other embodiments. Rather than restricted to the detailed description, the scope of the disclosure is defined by the appended claims.

It is noteworthy that the detailed description below is accompanied by different embodiments or examples for use in implementing various features of the disclosure. Specific embodiments or examples about components and arrangement thereof are presented below to simplify the description of the disclosure; however, the specific embodiments or examples are illustrative rather than restrictive. For example, the dimensions of the disclosed components are not restricted to any disclosed ranges or values but depend on requirements of a related manufacturing process and/or expected characteristics of a related device. In addition, concepts, such as “forming a first feature above or on a second feature,” as disclosed in the description below may apply to embodiments, such as “forming a first feature and a second feature in such a way that the first and second features are in direct contact with each other,” and “forming a first feature and a second feature in such a way that an additional feature is formed between the first and second features to ensure that the contact between the first and second features is indirect.” For the sake of conciseness and clarity, the accompanying drawings can be drawn in different scales in order to depict various features, not to mention leaving out some layers/features.

In addition, for explanatory purposes, expressions about spatial relationships, such as “beneath,” “below,” “lower,” “above” and “upper,” are used herein to explain the relationship between one component (or feature) and another component (or feature), as shown in the accompanying drawings. The expressions about spatial relationships are intended to indicate any other directions in which the components are used or operated in addition to the directions depicted in the accompanying drawings. The components may have any other directions (be rotated by 90 degrees or be aligned with another direction), and the expressions about spatial relationships can be construed accordingly.

In some embodiments of the disclosure, a management system for a plurality of probe cards comprises a storage device, inspection device and conveying device. The storage device stores a plurality of probe cards and automatically selects and moves a required one. The inspection device automatically moves and inspects whether functions of the probe cards are normal before the probe cards are stored in the storage device. The conveying device conveys the probe cards between the storage device, the inspection device and a DUT testing device. The storage device, inspection device and conveying device automatically perform related operations according to different device control signals. Therefore, the management system of the disclosure can perform probe card management efficiently and precisely. The fine structures of the management system of the disclosure and explanation thereof are presented below.

Referring to FIG. 1, there is shown a schematic view of a management system 1 for a plurality of probe cards 9 according to some embodiments of the disclosure. Specifically, the management system 1 includes a storage device 11, an inspection device 13 and a conveying device 15. The storage device 11 stores at least one of the probe cards 9. The inspection device 13 inspects at least one of the probe cards 9. In some embodiments, at least one conveying device control signal 10 is transmitted to the conveying device 15 to control the conveying device 15 to convey at least one of the probe cards 9 between the storage device 11, the inspection device 13 and a DUT testing device 8 (also known as “tester”).

For example, the conveying device control signal 10 includes: (1) a first conveying device control signal 101 for controlling the conveying device 15 to convey the probe cards 9 from the DUT testing device 8 to the inspection device 13; (2) a second conveying device control signal 102 for controlling the conveying device 15 to convey the probe cards 9 from the inspection device 13 to the storage device 11; (3) a third conveying device control signal 103 for controlling the conveying device 15 to convey the probe cards 9 from the inspection device 13 to a probe card recycling station 7; and (4) a fourth conveying device control signal 104 for controlling the conveying device 15 to convey the probe cards 9 from the storage device 11 to the DUT testing device 8. In some embodiments, the probe cards 9 are stored in the storage device 11 after being inspected by the inspection device 13 to be functioning well.

In some embodiments, when the DUT testing device 8 has to use a specific probe card 9 stored in the storage device 11, the DUT testing device 8 transmits the fourth conveying device control signal 104 to the conveying device 15 via a network to instruct the conveying device 15 to move the specific probe card 9 from the storage device 11 to the DUT testing device 8. Therefore, after receiving the fourth conveying device control signal 104, the conveying device 15 moves to the storage device 11 and conveys the specific probe card 9 from the storage device 11 to the DUT testing device 8, allowing the specific probe card 9 to be mounted on the DUT testing device 8 to facilitate a subsequent related test.

In some embodiments, after the process of the use of the specific probe card 9 on the DUT testing device 8 has temporarily ended, the DUT testing device 8 transmits the first conveying device control signal 101 to the conveying device 15 via a network to instruct the conveying device 15 to convey the specific probe card 9 from the DUT testing device 8 to the inspection device 13. After receiving the first conveying device control signal 101, the conveying device 15 moves to the DUT testing device 8 and conveys the specific probe card 9 dismounted from the DUT testing device 8 to the inspection device 13, allowing the inspection device 13 to inspect whether a function of the specific probe card 9 is normal. After being inspected to be functioning well, the probe card 9 is stored in the storage device 11 to ensure that all the probe cards 9 stored in the storage device 11 are functioning well. In some embodiments, the storage device 11 and the inspection device 13 are combined to allow the inspection device 13 to directly move the specific probe card 9 to the storage device 11 for storage after inspecting that the function of the specific probe card 9 is normal.

In some embodiments, upon completion of the inspection of the specific probe card 9 on the inspection device 13, the inspection device 13 transmits the second conveying device control signal 102 or third conveying device control signal 103 to the conveying device 15 via a network according to an inspection result to instruct the conveying device 15 to move the specific probe card 9 from the inspection device 13 to: (1) the storage device 11; or (2) the probe card recycling station 7. When the specific probe card 9 is inspected to be functioning well, the specific probe card 9 is moved to the storage device 11, i.e., scenario (1), and the conveying device 15 receives the second conveying device control signal 102 to thereby move to the inspection device 13 and directly convey the specific probe card 9 dismounted from the inspection device 13 to the storage device 11 for the storage device 11 to store the specific probe card 9. When the specific probe card 9 is inspected to be malfunctioning, the specific probe card 9 is moved to the probe card recycling station 7, i.e., scenario (2), and the conveying device 15 receives the third conveying device control signal 103 to thereby move to the inspection device 13 and convey the specific probe card 9 dismounted from the inspection device 13 to the probe card recycling station 7, allowing the probe card recycling station 7 to repair or recycle the malfunctioning probe card 9.

Referring to FIG. 2A, there is shown a schematic view of a management system 2 for a plurality of probe cards 6 according to some embodiments of the disclosure. Specifically, the management system 2 includes a storage device 21, an inspection device 23 and a conveying device 25. The storage device 21 includes a plurality of storage units 211 and a first moving unit 213. The storage units 211 store at least one of the probe cards 6. The first moving unit 213 moves the probe cards 6 between the storage units 211 and external devices (for example, the conveying device 25 and the inspection device 23). The inspection device 23 includes an inspection unit 231 and a second moving unit 233. The inspection unit 231 holds and inspects at least one of the probe cards 6. The second moving unit 233 moves the probe cards 6 between the inspection unit 231 and external devices (for example, the conveying device 25 and the storage device 21).

In some embodiments, at least one conveying device control signal 20 is transmitted to the conveying device 25 to control the conveying device 25 to convey at least one of the probe cards 6 between the storage device 21, the inspection device 23 and a DUT testing device 5. For example, the conveying device control signal 20 includes: (1) a first conveying device control signal 201 for controlling the conveying device 25 to convey the probe cards 6 from the DUT testing device 5 to the inspection device 23; (2) a second conveying device control signal 202 for controlling the conveying device 25 to convey the probe cards 6 from the inspection device 23 to the storage device 21 or the DUT testing device 5; (3) a third conveying device control signal 203 for controlling the conveying device 25 to convey the probe cards 6 from the inspection device 23 to a probe card recycling station 4; and (4) a fourth conveying device control signal 204 for controlling the conveying device 25 to convey the probe cards 6 from the storage device 21 to the DUT testing device 5.

In some embodiments, at least one storage device control signal 22 is transmitted to the storage device 21 to control the storage device 21. For example, the storage device control signal 22 includes a first storage device control signal 221 for controlling the first moving unit 213 of the storage device 21 to select specific probe cards 6 from the plurality of storage units 211 and move the selected specific probe cards 6 to the conveying device 25. In some embodiments, the probe cards 6 are stored in the storage device 21 after being inspected by the inspection device 23 to be functioning well.

In some embodiments, at least one inspection device control signal 24 is transmitted to the inspection device 23 to control the inspection device 23. For example, the inspection device control signal 24 includes a first inspection device control signal 241 for controlling the second moving unit 233 of the inspection device 23 to move the probe cards 6 between the inspection unit 231 and external devices (for example, the conveying device 25 and the storage device 21).

In some embodiments, when the DUT testing device 5 needs to use a specific probe card 6 conforming with a specific probe specification and stored in the storage device 21, the DUT testing device 5 transmits via a network: (1) the first storage device control signal 221 to the storage device 21 to instruct the first moving unit 213 of the storage device 21 to select the specific probe card 6 from the plurality of storage units 211 and move the selected specific probe card 6 to the conveying device 25; and (2) the fourth conveying device control signal 204 to the conveying device 25 to instruct the conveying device 25 to move the specific probe card 6 from the storage device 21 to the DUT testing device 5.

Specifically, after the storage device 21 has received the first storage device control signal 221, the first moving unit 213 selects the specific probe card 6 conforming with a specific probe specification from the plurality of storage units 211 according to a probe card storage log file (not shown) and gets ready to move the selected specific probe card 6 to the conveying device 25. Meanwhile, after having received the fourth conveying device control signal 204, the conveying device 25 not only moves to the storage device 21 but also conveys the specific probe card 6 to the DUT testing device 5 after the first moving unit 213 has moved the selected specific probe card 6 to the conveying device 25, allowing the specific probe card 6 to be mounted on the DUT testing device 5 to facilitate a subsequent related test.

In some embodiments, after the process of the use of the specific probe card 6 on the DUT testing device 5 has temporarily ended, the DUT testing device 5 transmits the first conveying device control signal 201 to the conveying device 25 via a network to instruct the conveying device 25 to move the specific probe card 6 from the DUT testing device 5 to the inspection device 23. After receiving the first conveying device control signal 201, the conveying device 25 moves to the DUT testing device 5 and conveys the specific probe card 6 dismounted from the DUT testing device 5 to the inspection device 23.

After the inspection device 23 has confirmed that the conveying device 25 has already finished the movement of the specific probe card 6, the second moving unit 233 moves the specific probe card 6 on the conveying device 25 to the inspection unit 231 according to the arrival of the conveying device 25 and the first inspection device control signal 241, allowing the inspection unit 231 to inspect whether a function of the specific probe card 6 is normal or not. The specific probe card 6 is stored in the storage device 21 after being inspected to be functioning well, ensuring that all the probe cards 6 stored in the storage device 21 are functioning well. In some embodiments, the storage device 21 and the inspection device 23 are combined to allow the inspection device 23 to directly move the specific probe card 6 to the storage device 21 for storage after inspecting that the specific probe card 6 is functioning well.

In some embodiments, upon completion of the inspection of the specific probe card 6 on the inspection unit 231 of the inspection device 23, the inspection unit 231 transmits the second conveying device control signal 202 or third conveying device control signal 203 to the conveying device 25 via a network according to an inspection result to instruct the conveying device 25 to move the specific probe card 6 from the inspection device 23 to: (1) the storage device 21 or the DUT testing device 5; or (2) the probe card recycling station 4.

When the specific probe card 6 is inspected to be functioning well, the specific probe card 6 is moved to the storage device 21, i.e., scenario (1), and the conveying device 25 receives the second conveying device control signal 202 to thereby move to the inspection device 23. After confirming the arrival of the conveying device 25, the second moving unit 233 of the inspection device 23 dismounts the specific probe card 6 and loads the specific probe card 6 onto the conveying device 25 according to the first inspection device control signal 241 such that the conveying device 25 conveys the specific probe card 6 to the storage device 21 or the DUT testing device 5, allowing the specific probe card 6 to be stored in the storage device 21 or a related test to be performed by the DUT testing device 5 with the specific probe card 6 continuously.

When the specific probe card 6 is inspected to be malfunctioning, the specific probe card 6 is moved to the probe card recycling station 4, i.e., scenario (2), and the conveying device 25 receives the third conveying device control signal 203 to thereby move to the inspection device 23. After confirming the arrival of the conveying device 25, the second moving unit 233 of the inspection device 23 dismounts the specific probe card 6 and loads the specific probe card 6 onto the conveying device 25 according to the first inspection device control signal 241 such that the conveying device 25 conveys the specific probe card 6 to the probe card recycling station 4, allowing the probe card recycling station 4 to repair or recycle the malfunctioning probe card 6.

In some embodiments, all the device control signals for use in the management system 2 are centrally managed and transmitted by the DUT testing device 5. Specifically, the device control signals (for example, the conveying device control signal 20, storage device control signal 22 and inspection device control signal 24) for use in the management system 2 are transmitted by the DUT testing device 5 to different devices via a wired or wireless network to perform related operations.

For example, the storage device control signal 22 includes: a control instruction for instructing the first moving unit 213 to select the specific probe card 6 from the storage units 211 at a specific position; a control instruction for instructing the first moving unit 213 to select the storage units 211 at the specific position and place the specific probe card 6 in them; and a control instruction for instructing the first moving unit 213 to move between the conveying device 25 and the storage units 211.

For example, the inspection device control signal 24 includes: a control instruction for instructing the second moving unit 233 to dismount the specific probe card 6 from the inspection unit 231; a control instruction for instructing the second moving unit 233 to mount the specific probe card 6 onto the inspection unit 231; and a control instruction for instructing the second moving unit 233 to move between the inspection unit 231 and the conveying device 25.

For example, the conveying device control signal 20 includes a control instruction for instructing the conveying device 25 to convey the specific probe card 6 between the storage device 21, the inspection device 23, the DUT testing device 5 and the probe card recycling station 4.

Referring to FIG. 2B, there is shown a schematic view of a management system 2′ according to some embodiments of the disclosure. Specifically, the management system 2′ is similar to the management system 2 except that the management system 2′ further includes a plurality of inspection devices 23, a plurality of the conveying devices 25 and a central control device 27. In some embodiments, the plurality of inspection devices 23 and the plurality of conveying devices 25 enhance the flexibility of the inspections and movements of the plurality of probe cards 6. In some embodiments, the device control signals for use in the management system 2′ are managed centrally by the central control device 27 and transmitted to the storage device 21, the plurality of inspection devices 23 and the plurality of conveying devices 25 via a wired or wireless network. Therefore, users can operate the management system 2′ with the central control device 27.

In some embodiments, in addition to the signal 20 dedicated to the conveying devices 25, the management system 2′ transmits at least one conveying device control signal 26 (for example, a fifth conveying device control signal 261) to another conveying device 25 to control the another conveying device 25 to convey at least one of the probe cards 6 between the storage device 21, the inspection device 23 and the DUT testing device 5. The signal 26 is substantively the same as the signal 22 and thus is not reiterated herein.

The conveying devices 15, 25 in the aforesaid embodiment each comprise an automated guided vehicle (AGV), and the moving units 213, 233 in the aforesaid embodiment each comprise robotic arms mounted on the devices, without placing any limitation on the embodiment of the conveying devices of the disclosure.

In conclusion, in some embodiments of the disclosure, a probe card management system comprises: (1) a storage device for storing a plurality of probe cards and automatically selecting and moving the required probe cards; (2) an inspection device for automatically moving and inspecting whether the probe cards are functioning well or not; and (3) a conveying device for automatically conveying the probe cards between the storage device, the inspection device and a DUT testing device. Therefore, the management system of the disclosure is capable of performing probe card management efficiently and precisely.

Although the disclosure and advantages thereof are described above in detail, it should be understood that various changes, replacements and substitutions can be made to the embodiments of the disclosure without departing from the spirit and scope defined by the appended claims of the disclosure. For example, the aforesaid manufacturing processes can be implemented with different methods and replaced with other manufacturing processes or combinations thereof.

The scope of the disclosure is not restricted to specific embodiments of any processes, machines, manufacturing, matter compositions, means, methods and steps described herein. The disclosure described herein enables persons skilled in the art to implement the disclosure with any existing or potential processes, machines, manufacturing, matter compositions, means, methods or steps having the same function or capable of achieving substantially the same result as disclosed in the aforesaid embodiments. Therefore, processes, machines, manufacturing, matter compositions, means, methods and steps fall within the scope of the appended claims of the disclosure.

What is claimed is:

1. A management system for a plurality of probe cards, comprising:
a storage device;
an inspection device; and
a conveying device for receiving a first conveying device control signal and conveying a first probe card of the probe cards from a DUT testing device to the inspection device according to the first conveying device control signal,
wherein the inspection device inspects whether a function of the first probe card is normal, and the first probe card is stored in the storage device after the function of the first probe card is inspected as normal.

2. The management system of claim 1, wherein the conveying device conveys the first probe card to the storage device according to a second conveying device control signal when the function of the first probe card is inspected as normal.

3. The management system of claim 1, further comprising:
a probe card recycling station;
wherein when the first probe card is inspected to be malfunctioning, the first probe card is conveyed by the conveying device to the probe card recycling station according to a third conveying device control signal

4. The management system of claim 1, wherein the storage device further comprises:
a plurality of storage units for storing at least one of the probe cards; and
a first moving unit for moving at least one of the probe cards.

5. The management system of claim 4, wherein the first moving unit of the storage device is configured to:
receive a first storage device control signal;
select a second probe card from the storage units according to the first storage device control signal; and
move the second probe card from the storage device to the conveying device,
wherein the conveying device conveys the second probe card to the DUT testing device according to a fourth conveying device control signal to allow the second probe card to be mounted on the DUT testing device.

6. The management system of claim 5, wherein the first moving unit selects the second probe card conforming with a specification of the DUT testing device from the storage units according to the first storage device control signal.

7. The management system of claim 5, wherein the first moving unit selects the second probe card conforming with a specification of a probe card from the storage units according to the first storage device control signal.

8. The management system of claim 1, wherein the inspection device further comprises:
an inspection unit for inspecting the first probe card; and
a second moving unit for moving the first probe card.

9. The management system of claim 8, wherein the second moving unit of the inspection device is configured to:
move the first probe card from the conveying device to the inspection unit or moves the first probe card from the inspection unit to the conveying device.

10. The management system of claim 1, further comprising:
a central control device for transmitting a plurality of device control signals to the storage device, the inspection device and the conveying device to control the storage device, the inspection device and the conveying device.

11. The management system of claim 1, further comprising:
another inspection device for inspecting a third probe card of the probe cards.

12. The management system of claim 1, further comprising:
another conveying device for receiving a fifth conveying device control signal and conveying at least one of the probe cards between the storage device, the inspection device and the DUT testing device according to the fifth conveying device control signal.
